(19) United States
(12) Patent Application Publication
(10) Pub. No.: US 2025/0044372 A1
(43) Pub. Date: Feb. 6, 2025

(54) CIRCUIT FOR CONDUCTION TESTING OF POWER SUPPLY OF PLASMA GLOBE LAMP

(71) Applicant: CHANGZHOU SHENGDAN ELECTRICAL EQUIPMENT CO., LTD., Changzhou (CN)

(72) Inventor: Dan ZHANG, Changzhou (CN)

(21) Appl. No.: 18/925,127

(22) Filed: Oct. 24, 2024

Related U.S. Application Data
(63) Continuation of application No. PCT/CN2024/109197, filed on Aug. 1, 2024.

(30) Foreign Application Priority Data
Aug. 2, 2023 (CN) 202322072888.7

(51) Int. Cl. G01R 31/42; G01R 31/44; H02M 1/42; H05B 41/282

(52) U.S. Cl. CPC G01R 31/42; G01R 31/44; H02M 1/4233; H05B 41/2828

(57) ABSTRACT

A circuit for conduction testing of a power supply of a plasma globe lamp includes a rectifying circuit and a switching power supply, the circuit for conduction testing of the power supply of the plasma globe lamp is connected with an alternating current output end of an external power supply, a first end of the rectifying circuit is connected with the alternating current output end of the external power supply, a second end of the rectifying circuit is connected with the switching power supply, and the rectifying circuit is configured to convert an alternating current output by the alternating current output end into a direct current and to output the direct current to the switching power supply, and the rectifying circuit includes at least two diodes and a substrate, and all the at least two diodes are integrated in the substrate.

### CROSS-REFERENCE TO RELATED APPLICATION

This application is a continuation of PCT application serial no. PCT/CN2024/109197, filed on Aug. 1, 2024, which claims the priority and benefit of Chinese patent application serial no. 202322072888.7, filed on Aug. 2, 2023. The entirety of PCT application serial no. PCT/CN2024/109197 and Chinese patent application serial no. 202322072888.7 are hereby incorporated by reference herein and made a part of this specification.

### TECHNICAL FIELD

The present application relates to the field of conduction testing, and more particularly, to a circuit for conduction testing of a power supply of a plasma globe lamp.

### BACKGROUND ART

Conduction testing is a method for testing the radiation performance of an electronic device and is commonly used for evaluating the electromagnetic compatibility of a device. A magic lamp, also called a plasma globe lamp, is an ornamental product which is mainly controlled by a control circuit.

The control circuit mainly includes a switching power supply, an adapter and a plurality of components, which are respectively integrated in different circuit boards. When it is necessary to detect the conduction and radiation performance of a plasma globe lamp, a worker must connect all the circuit boards one by one to perform a testing.

When actually testing the conduction and radiation performance of a plasma globe lamp, the operation process is relatively complicated, and costs are relatively high as the switching power supply, the adapter and the different components are respectively integrated in different circuit boards, which needs to be improved.

### SUMMARY

In order to improve the above problems, the present application provides a circuit for conduction testing of a power supply of a plasma globe lamp.

The circuit for conduction testing of a power supply of a plasma globe lamp provided in the present application adopts the following technical solution.

A circuit for conduction testing of a power supply of a plasma globe lamp includes a rectifying circuit and a switching power supply, the circuit for conduction testing of the power supply of the plasma globe lamp is connected with an alternating current output end of an external power supply, a first end of the rectifying circuit is connected with the alternating current output end of the external power supply, a second end of the rectifying circuit is connected with the switching power supply, and the rectifying circuit is configured to convert an alternating current output by the alternating current output end into a direct current and to output the direct current to the switching power supply, and the rectifying circuit includes at least two diodes and a substrate, and all the at least two diodes are integrated in the substrate.

By adopting the above technical solution, the rectifying circuit receives an external alternating current, converts the alternating current into a direct current, and then delivers the direct current into the switching power supply, so as to detect the conduction and radiation performance of the power supply of the plasma globe lamp. Herein, the rectifying circuit and the switching power supply integrated in the same substrate improve the integration level of the whole test circuit, reduce the step, in which the worker spends additional time in assembling the test circuit, and save a part of costs, which improves the efficiency of detecting the conduction and radiation performance of the plasma globe lamp by the worker.

Optionally, the rectifying circuit is a rectifier bridge BD1, a first end of the rectifier bridge BD1 is connected with the alternating current output end of the external power supply, and a second end of the rectifier bridge BD1 is connected with the switching power supply.

By adopting the above technical solution, the rectifier bridge performs a rectification and then outputs a direct current which meets the requirements for testing the power supply of the plasma globe lamp, so as to provide a relatively stable current for the switching power supply, and to improve the stability of the test circuit in operation, thereby improving the conduction and radiation performance of the test circuit, namely, improving the electromagnetic compatibility of the test circuit.

Optionally, the rectifying circuit is a full-wave rectifying circuit, the full-wave rectifying circuit includes a first diode and a second diode, a first end of the first diode and a first end of the second diode are both connected with the alternating current output end of the external power supply, and a second end of the first diode and a second end of the second diode are both connected with the switching power supply.

Optionally, a filtering circuit is provided between the rectifying circuit and the alternating current output end of the external power supply, the filtering circuit is integrated in the substrate, the filtering circuit includes a first resistor R1, a second resistor R2 and a first capacitor C1, the first resistor R1 is connected with the second resistor R2 in series, and the first capacitor C1 is connected with the first resistor R1 is connected with the second resistor R2 in parallel.

By adopting the above technical solution, the filtering circuit formed by the first capacitor, the first resistor and the second resistor screens the input alternating current, such that signals in a frequency range required by the detection circuit in operation may normally pass through, which reduces clutter signals in current source signals and improves the power supply stability of the alternating current output end, and so the rectifying circuit may more stably convert the incoming alternating current. Additionally, an electromagnetic and capacitive resonance function is achieved in the test circuit, which increases the anti-interference capability of the circuit and improves the conduction and radiation performance of the whole test circuit, and thus improving the electromagnetic compatibility of the test circuit.

Optionally, a plug-in circuit is further included, the plug-in circuit includes a second capacitor, and the second capacitor is connected across a grounding terminal at an alternating current side and a grounding terminal at a direct current side.

By adopting the above technical solution, the second capacitor plays the role of increasing the electromagnetic compatibility, so that a grounding loop of the second capacitor is not likely to be interfered by a loop where the adjacent filtering circuit and rectifying circuit are positioned.

Optionally, the second capacitor has a capacitance of 2.2 nF.

Optionally, the rectifying circuit is connected with the alternating current output end of the external power supply through a first plug-in unit and a second plug-in unit, the first plug-in unit is connected with a live wire, the second plug-in unit is connected with a neutral wire, the plug-in circuit is connected with the grounding terminal at the alternating current side through a third plug-in unit, the first resistor R1 and the second resistor R2 are connected to the first plug-in unit and the second plug-in unit in parallel, and the first capacitor C1 is connected to the first plug-in unit and the second plug-in unit in parallel.

By adopting the above technical solution, when the rectifying circuit is connected to the external alternating current power supply, the first plug-in unit and the second plug-in unit are respectively connected with the live wire and the neutral wire, so as to acquire a high-voltage alternating current. Moreover, the first resistor, the second resistor and the first capacitor which are connected to the first plug-in unit and the second plug-in unit in parallel enable the electromagnetic and capacitive resonance to be formed in the circuit, so that the anti-interference capability of the circuit is increased, and the conduction and radiation performance of the whole test circuit is improved, namely, the electromagnetic compatibility of the whole test circuit is improved.

Optionally, a fuse resistor F1 is connected with the first plug-in unit.

By adopting the above technical solution, by means of the fuse resistor, a resistance value in a loop where the first plug-in unit is positioned is increased, which plays a protective role on the loop where the first plug-in unit is positioned, so that the rectifying circuit may be safely connected to a power supply with a relatively high power.

In summary, the present application includes at least one of the following beneficial technical effects.

The rectifying circuit and the switching power supply integrated in the same substrate improve the integration level of the whole test circuit, reduce the step, in which the worker spends additional time in assembling the test circuit, and save a part of costs, which improves the efficiency of detecting the conduction and radiation performance of the plasma globe lamp by the worker;

The rectifier bridge converts the alternating current into a direct current which meets the requirements for testing the power supply of the plasma globe lamp, so as to provide a relatively stable current for the switching power supply, and to improve the stability of the test circuit in operation, thereby improving the conduction and radiation performance of the test circuit, namely, improving the electromagnetic compatibility of the test circuit.

The first resistor R1, the second resistor R2 and the first capacitor C1 which are connected between the first plug-in unit and the second plug-in unit in parallel enable the electromagnetic and capacitive resonance to be formed, so that the anti-interference capability of the circuit is increased, namely, the electromagnetic compatibility of the whole test circuit is improved, and a better electromagnetic compatibility may be obtained by increasing or reducing the number of capacitors.

### BRIEF DESCRIPTION OF THE DRAWINGS

FIG. 1 is a circuit diagram for showing a filtering circuit, a rectifying circuit and a switch circuit;

FIG. 2 is a circuit diagram according to Embodiment 1 of the present application; and

FIG. 3 is a circuit diagram according to Embodiment 2 of the present application.

### DETAILED DESCRIPTION

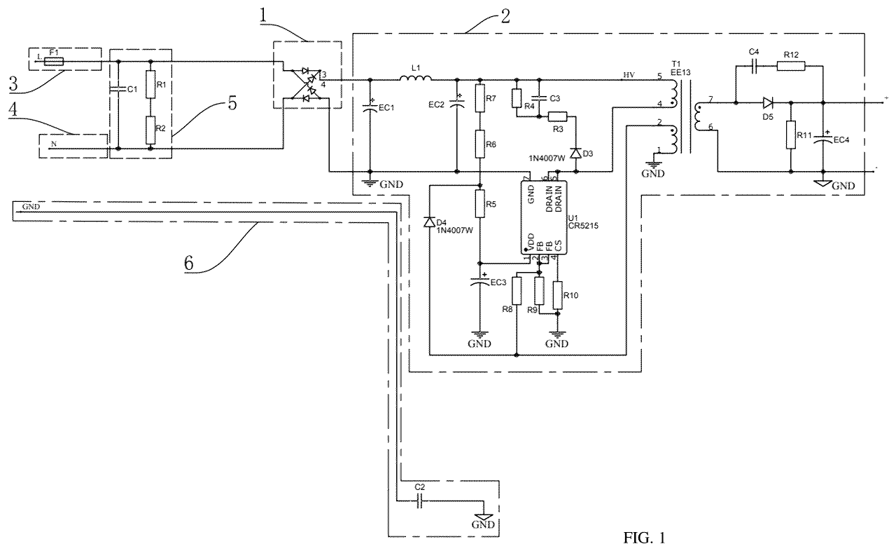

The present application is described in further detail below in conjunction with FIG. 1 to FIG. 3.

### Embodiment 1

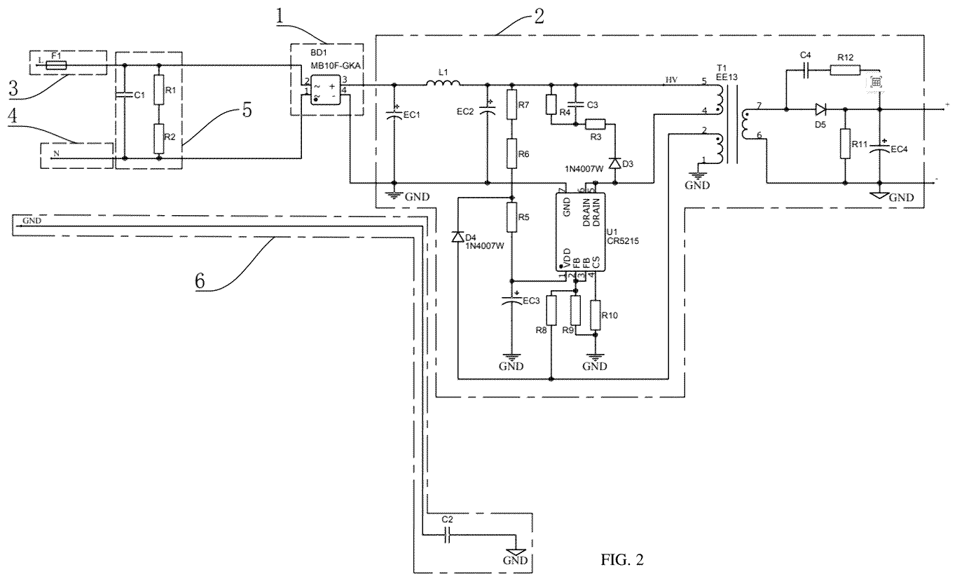

Embodiment 1 of the present application discloses a circuit for conduction testing of a power supply of a plasma globe lamp. Referring to FIG. 1 and FIG. 2, the circuit for conduction testing of a power supply of a plasma globe lamp is connected to an alternating current output end of an external power supply, and includes a rectifying circuit 1 and a switching power supply 2. One end of the rectifying circuit 1 is connected to the alternating current output end of the external power supply, and the other end thereof is connected to the switching power supply 2. The rectifying circuit 1 is used for converting an alternating current output from the alternating current output end into a direct current and outputting the direct current to the switching power supply 2. The rectifying circuit 1 includes at least two diodes and a substrate, and all the diodes are integrated in the substrate. When actual using the test circuit, the rectifying circuit 1 and the switching power supply 2 integrated in the same substrate improve an integration level of the whole test circuit, reduce the step, in which the worker spends additional time in assembling the test circuit, and save a part of costs, so as to improve the efficiency of testing the conduction and radiation performance of the plasma globe lamp by the worker.

Referring to FIG. 2, the rectifying circuit 1 is designed as a rectifier bridge BD1, one end of the rectifier bridge BD1 is connected to the alternating current output end of the external power supply through a first plug-in unit 3 and a second plug-in unit 4, and the other end thereof is connected to the switching power supply 2. The first plug-in unit 3 is connected to a live wire of the external power supply, and the second plug-in unit 4 is connected to a neutral wire of the external power supply. The rectifier bridge BD1 is a rectifying element, with a specific model of MB10F-GKA.

In order to improve the stability of the rectifying circuit 1 in operation, a filtering circuit 5 is provided between the rectifying circuit 1 and the AC output end of the external power supply, and the filtering circuit 5 is integrated in the substrate. The filtering circuit 5 includes a first resistor R1, a second resistor R2 and a first capacitor C1, and the first resistor R1 and the second resistor R2 are connected in series and then connected with the first plug-in unit 3 and the second plug-in unit 4 in parallel. The first capacitor C1 is connected with the first plug-in unit 3 and the second plug-in unit 4 in parallel. The first capacitor C1 is an electrolytic capacitor, so that the electromagnetic compatibility between the first plug-in unit 3 and the second plug-in unit 4 is increased as the capacitance and the inductance are increased. The specific models of the first capacitor C1, the first resistor R1 and the second resistor R2 are selected by the worker according to actual situations, and are not disclosed and described in detail in this embodiment.

After the test power supply is connected with the external alternating current power supply, the first plug-in unit 3 and the second plug-in unit 4 deliver the alternating current to the filtering circuit 5. Herein, the filtering circuit 5 including the first capacitor C1, the first resistor R1 and the second resistor R2 screens the input alternating current, so that signals in a frequency range required by a detection circuit in operation may normally pass through, which reduces clutter signals in current source signals, and thus improving the power supply stability of the AC output end.

The screened alternating current is then delivered into the rectifier bridge BD1, and after the alternating current is rectified by the rectifier bridge BD1, a direct current which meets the requirements of the test circuit is output to the switching power supply 2, so as to provide a relatively stable current for the switching power supply 2, thereby improving the stability of the test circuit in operation, and thus improving the conduction and radiation performance of the whole test circuit, namely, improving the electromagnetic compatibility of the whole test circuit.

Referring to FIG. 2, a fuse resistor F1 is connected to the first plug-in unit 3, and with the fuse resistor F1, the resistance value in the loop where the first plug-in unit 3 is positioned is increased, which plays a protective role on the loop where the first plug-in unit 3 is positioned, so that the rectifying circuit 1 may be safely connected with a power supply with a relatively high power.

Referring to FIG. 2, a third plug-in unit 6 is connected to a grounding terminal of the alternating current output end of the external power supply, and a plug-in circuit is connected to the third plug-in unit 6. The plug-in circuit includes a second capacitor C2, and the second capacitor C2 is connected across a grounding terminal at an alternating current side and a grounding terminal at a direct current side. In the embodiment of the present application, one or more second capacitors C2 may be provided according to actual use requirements of the test circuit, and when a plurality of second capacitors C2 are provided, all the second capacitors C2 are connected in series with each other. Moreover, the second capacitor C2 has a capacitance of 2.2 nF. The second capacitor C2 plays the role of increasing the electromagnetic compatibility, so that a grounding loop of the second capacitor C2 is not likely to be interfered by a loop where the adjacent filtering circuit 5 and rectifying circuit 1 are positioned.

Referring to FIG. 2, the rectifier bridge BD1 has a first input end and a second input end, the first plug-in unit 3 is connected with the first input end, and the second plug-in unit 4 is connected with the second input end. The switching power supply 2 includes a control chip U1 and a transformer T1, by which a specific model of the control chip U1 is CR5215. The control chip U1 has a first pin, a second pin, a third pin, a fourth pin, a fifth pin, a sixth pin and a seventh pin. The rectifier bridge BD1 has two output ends, one of the output ends is connected with the seventh pin of the control chip U1, and the seventh pin is a grounding pin. The transformer T1 is a high-frequency transformer with a specific model of EE13 and a working frequency of 65 KHZ.

The other output end of the rectifier bridge BD1 is firstly connected to a secondary coil of the transformer T1 and then connected to the fifth pin and the sixth pin of the control chip U1, and the fifth pin and the sixth pin are drain access terminals of the control chip U1.

Referring to FIG. 2, a first electrolytic capacitor EC1 and a second electrolytic capacitor EC2 are connected in parallel between the two output ends of the rectifier bridge BD1, and the capacitances of the first electrolytic capacitor EC1 and the second electrolytic capacitor EC2 are both 4.7 μF. Moreover, a first inductor L1 is connected between the rectifier bridge BD1 and the fifth pin of the control chip U1, the first inductor L1 is connected with the first electrolytic capacitor EC1 and the second electrolytic capacitor EC2 in parallel to form an oscillating circuit, so as to generate a stable high-frequency signal.

Input ends of the fifth pin and the sixth pin are connected, the connection thereof form a loop together with one of the secondary coils. A first steering diode D3 and a third resistor R3 are sequentially connected in loops of the fifth pin and the sixth pin, one end of the third resistor R3 away from the first steering diode D3 is connected to the rectifier bridge BD1, and a fourth resistor R4 and a third capacitor C3 are connected in parallel between the rectifier bridge BD1 and the first steering diode D3.

Referring to FIG. 2, the first pin of the control chip U1 is connected with an output end of the first inductor L1, and a fifth resistor R5, a sixth resistor R6 and a seventh resistor R7 are connected in series between the control chip U1 and the first inductor L1. The first pin is a power supply access terminal of the control chip U1, and when the received power supply reaches a rated voltage value, the control chip U1 is started and begins to work. In the embodiment of the present application, the control chip U1 is used for detecting current and voltage values between the rectifier bridge BD1 and the transformer T1, and when the voltage value or the current value exceeds a set threshold, the control chip U1 controls the circuit to be disconnected, so as to improve the safety of the circuit. Moreover, a third electrolytic capacitor EC3 is further connected at the connection of the first pin and the fifth resistor R5, and one end of the third electrolytic capacitor EC3 away from the fifth resistor R5 is grounded.

The second pin and the third pin are feedback input ends, the second pin is connected with the third pin, and the connection between the second pin and the third pin is connected in series with an eighth resistor R8 and a ninth resistor R9. The other end of the ninth resistor R9 is connected to the fourth pin. A tenth resistor R10 is connected to an output end of the fourth pin, and one end of the tenth resistor R10 away from the fourth pin is grounded. In addition, the eighth resistor R8 is connected with one secondary coil of the transformer T1, one end of this secondary coil is grounded, and the other end of this secondary coil is connected to the fifth resistor R5. Moreover, a second steering diode D4 is connected between the secondary coil and the fifth resistor R5, and specific models of the first steering diode D3 and the second steering diode D4 are both 1N4007W.

Referring to FIG. 2, the transformer T1 has one tickler coil, and the tickler coil is connected to a charging terminal of the test circuit and delivers the direct current after voltage transformation and regulation to an electric equipment for power supply through the charging terminal. The tickler coil has a positive pole of an output end of the power supply and a negative pole of an input end of the power supply, a fourth electrolytic capacitor EC4 and an eleventh resistor R11 are connected in parallel between the positive pole of the output end of the power supply and the negative pole of the input end of the power supply, and the connection between the fourth electrolytic capacitor EC4 and the negative input end of the power supply is grounded. A third steering diode D5 is connected to the positive pole of the output end of the power supply, and a fourth capacitor C4 and a twelfth resistor R12 connected in series with each other are connected to the positive pole of the output end of the power supply, and the fourth capacitor C4 and the twelfth resistor R12 are connected with the third steering diode D5 in parallel.

The implementation principle of Embodiment 1 of the present application is as follows. The rectifying circuit 1 and the switching power supply 2 are integrated in the same substrate, so as to improve the integration level of the test circuit, reduce the step, in which the worker spends additional time in assembling the test circuit, and save a part of costs, which improves the efficiency of detecting the conduction and radiation performance of the power supply of the plasma globe lamp by the worker. Additionally, the rectifying circuit 1 and the filtering circuit 5 cooperate with each other to improve the stability of the test circuit in operation. The first capacitor C1, the first resistor R1 and the second resistor R2 are connected in parallel between the first plug-in unit 3 and the second plug-in unit 4, so that the electromagnetic and capacitive resonance is formed, which improves the anti-interference capability of the test circuit, namely, the electromagnetic compatibility of the whole test circuit is improved, and a better electromagnetic compatibility may be obtained by increasing and decreasing the number of capacitors.

### Embodiment 2

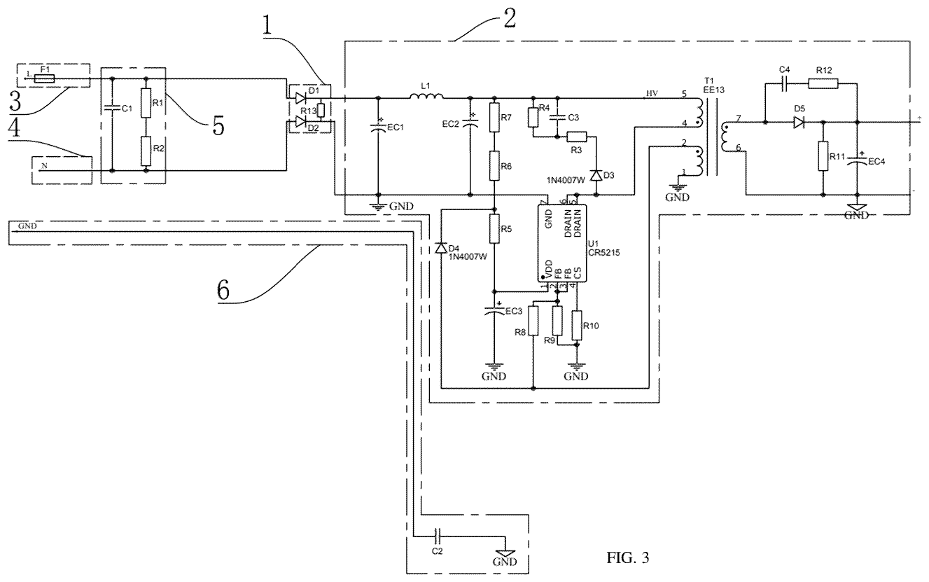

Referring to FIG. 3, the difference from Embodiment 1 of the present application is as follows: the rectifying circuit 1 is a full-wave rectifying circuit 1, the full-wave rectifying circuit 1 includes a first diode D1 and a second diode D2, the first diode D1 is positioned at a first plug-in unit 3, the second diode D2 is positioned at a second plug-in unit 4, and a connecting resistor R13 is connected in parallel between the first diode D1 and the second diode D2.

The implementation principle of Embodiment 2 of the present application is as follows: in an actual use process of the test circuit, the first diode D1 and the second diode D2 cooperate with each other to convert the alternating current of the external power supply into the direct current required for the testing of the power supply of the plasma globe lamp, so as to provide a relatively stable current for the switching power supply 2, which improves the stability of the test circuit in operation, thereby improving the conduction and radiation performance of the whole test circuit, namely, improving the electromagnetic compatibility of the test circuit.

The foregoing is all preferred embodiments of the present application and do not limit the protection scope of the present application on this basis, and therefore all equivalent changes made based on a structure, shape and principle of the present application shall fall within the scope of protection of the present application.

### LIST OF REFERENCE NUMERALS

1 rectifying circuit
2 switching power supply
3 first plug-in unit
4 second plug-in unit
5 filtering circuit
6 third plug-in unit

What is claimed is:

1. A circuit for conduction testing of a power supply of a plasma globe lamp, comprising a rectifying circuit and a switching power supply, wherein the circuit for conduction testing of the power supply of the plasma globe lamp is connected with an alternating current output end of an external power supply, a first end of the rectifying circuit is connected with the alternating current output end of the external power supply, a second end of the rectifying circuit is connected with the switching power supply, and the rectifying circuit is configured to convert an alternating current output by the alternating current output end into a direct current and to output the direct current to the switching power supply, and
the rectifying circuit comprises at least two diodes and a substrate, and all the at least two diodes are integrated in the substrate.

2. The circuit for conduction testing of a power supply of a plasma globe lamp according to claim 1, wherein the rectifying circuit is a rectifier bridge, a first end of the rectifier bridge is connected with the alternating current output end of the external power supply, and a second end of the rectifier bridge is connected with the switching power supply.

3. The circuit for conduction testing of a power supply of a plasma globe lamp according to claim 1, wherein the rectifying circuit is a full-wave rectifying circuit, the full-wave rectifying circuit comprises a first diode and a second diode, a first end of the first diode and a first end of the second diode are both connected with the alternating current output end of the external power supply, and a second end of the first diode and a second end of the second diode are both connected with the switching power supply.

4. The circuit for conduction testing of a power supply of a plasma globe lamp according to claim 1, further comprising a filtering circuit, wherein the filtering circuit is connected between the rectifying circuit and the alternating current output end of the external power supply, the filtering circuit is integrated in the substrate, the filtering circuit comprises a first resistor, a second resistor and a first capacitor, a first end of the first resistor is connected with a first end of the second resistor in series, a second end of the first resistor is connected with a positive pole of an input end of the rectifying circuit, a second end of the second resistor is connected with a negative pole of the input end of the rectifying circuit, and the first capacitor is connected between the positive pole of the input end of the rectifying circuit and the negative pole of the input end of the rectifying circuit in parallel.

5. The circuit for conduction testing of a power supply of a plasma globe lamp according to claim 4, further comprising a plug-in circuit, wherein the plug-in circuit comprises a second capacitor, and the second capacitor is connected across a grounding terminal at an alternating current side of the plug-in circuit and a grounding terminal at a direct current side of the plug-in circuit.

6. The circuit for conduction testing of a power supply of a plasma globe lamp according to claim 5, wherein the second capacitor has a capacitance of 2.2 nF.

7. The circuit for conduction testing of a power supply of a plasma globe lamp according to claim 5, further comprising a first plug-in unit, a second plug-in unit and a third plug-in unit, wherein the first plug-in unit is connected with a positive pole of the alternating current output end and the positive pole of the input end of the rectifying circuit, the second plug-in unit is connected with a negative pole of the alternating current output end and the negative pole of the input end of the rectifying circuit, and the plug-in circuit is connected to the grounding terminal at the alternating current side of the plug-in circuit through the third plug-in unit.

8. The circuit for conduction testing of a power supply of a plasma globe lamp according to claim 7, wherein a fuse resistor is connected to the first plug-in unit.
